(19) United States
(12) Patent Application Publication
(10) Pub. No.: US 2015/0234272 A1
(43) Pub. Date: Aug. 20, 2015

(54) METAL OXIDE NANOPARTICLES AND PHOTORESIST COMPOSITIONS

(71) Applicants: Intel Corporation, Santa Clara, CA (US); Cornell University, Ithaca, NY (US)

(72) Inventors: Chandrasekhar SARMA, Poughkeepsie, NY (US); Christopher K. OBER, Ithaca, NY (US); Emmanuel P. GIANNELIS, Ithaca, NY (US); Souvik CHAKRABARTY, Ithaca, NY (US)

(73) Assignees: Intel Corporation, Santa Clara, CA (US); Cornell University, Ithaca, NY (US)

(21) Appl. No.: 14/181,131

(22) Filed: Feb. 14, 2014

(51) Int. Cl. G03F 7/004

(52) U.S. Cl. CPC G03F 7/0045

(57) ABSTRACT

The invention provides new nanoparticles that include a Group 4 metal oxide core and a coating surrounding the core, where the coating contains a ligand according to Formula (I), or a carboxylate thereof. The invention also provides new photoresist compositions that include a photoacid generator and a ligand acid or carboxylate thereof, where pKa_{PAG} is lower than pKa_{LA}. Methods for patterning a substrate using the inventive photoresist composition are also provided.

### TECHNICAL FIELD

The present invention generally relates to metal oxide nanoparticles, and to photoresist compositions comprising metal oxide nanoparticles. More particularly, the present invention relates to nanoparticles having a Group 4 metal oxide core and an organic acid or carboxylate ligand, to photoresist compositions comprising metal oxide nanoparticles, and to methods of patterning that use the inventive photoresist compositions.

### BACKGROUND OF THE INVENTION

As described by Moore's law, the semiconductor industry drives down pattern dimensions in order to reduce transistor size and enhance processor speed at a rapid pace.

Thus, a need exists for improved materials, including photoresist compositions, that may help to facilitate producing integrated circuit features in the nanoscale/microscale regime.

While certain aspects of conventional technologies have been discussed to facilitate disclosure of the invention, Applicants in no way disclaim these technical aspects, and it is contemplated that the claimed invention may encompass one or more of the conventional technical aspects discussed herein.

In this specification, where a document, act or item of knowledge is referred to or discussed, this reference or discussion is not an admission that the document, act or item of knowledge or any combination thereof was, at the priority date, publicly available, known to the public, part of common general knowledge, or otherwise constitutes prior art under the applicable statutory provisions; or is known to be relevant to an attempt to solve any problem with which this specification is concerned.

### SUMMARY OF THE INVENTION

Briefly, the present invention satisfies the need for improved nanoparticles and photoresist compositions, and patterning methods using the compositions. The present invention may address one or more of the problems and deficiencies of the art discussed above. However, it is contemplated that the invention may prove useful in addressing other problems and deficiencies in a number of technical areas. Therefore, the claimed invention should not necessarily be construed as limited to addressing any of the particular problems or deficiencies discussed herein.

In one aspect, the invention provides a nanoparticle comprising:
a core comprising a Group 4 metal oxide; and
a coating surrounding the core, said coating comprising a ligand selected from an organic acid according to Formula (I):

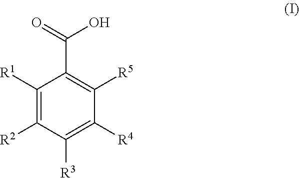

and a carboxylate thereof, wherein
R¹, R², R³, R⁴, and R⁵ are each individually selected from hydrogen, C₁₋₈ hydrocarbyl, halogen, hydroxyl, acyl, C₁₋₈hydrocarbylcarboxy, C₁₋₈ hydrocarbyloxy, C₁₋₈ hydrocarbyloxycarbonyl, carboxy, haloC₁₋₈hydrocarbyl, C₁₋₈ hydrocarbylthio, mercapto, cyano, thiocyanate, C₁₋₈hydrocarbylsulfinyl, C₁₋₈ hydrocarbylsulfonyl, aminosulfonyl, amino, nitro, and acetamide,
or two adjacent R¹-R⁵ groups, together with the carbon atoms to which they are attached, may form a 4-, 5- or 6-membered carbocyclic ring.

In another aspect, the invention provides a photoresist composition comprising:
a nanoparticle comprising:
   a core comprising a Group 4 metal oxide; and
   a coating surrounding the core, said coating comprising a ligand selected from an acid and a carboxylate thereof; and
a photoacid generator
   wherein said photoacid generator is capable, upon photodecomposition, of generating an acid having a pKa lower than the pKa of the ligand acid.

In another aspect, the invention provides a method for patterning a substrate, said method comprising:
forming a photoresist by applying on a substrate a photoresist composition according to the preceding aspect of the invention;
imagewise exposing a defined region of the applied composition; and
developing the photoresist using positive tone development or negative tone development.

Certain embodiments of the presently-disclosed metal oxide nanoparticles, photoresist compositions, and patterning methods have several features, no single one of which is solely responsible for their desirable attributes. Without limiting the scope of these metal oxide nanoparticles and photoresist compositions as defined by the claims that follow, their more prominent features will now be discussed briefly. After considering this discussion, and particularly after reading the section of this specification entitled “Detailed Description of the Invention,” one will understand how the features of the various embodiments disclosed herein provide a number of advantages over the current state of the art. These advantages may include, without limitation, providing photoresist compositions and components (e.g., metal oxide nanoparticles) for patternable films that are conducive to pattern formation under ultraviolet exposures (including extreme ultraviolet lithography (EUV)), and/or have one or more improved film parameters, including but not limited to resolution, line edge roughness, and sensitivity.

These and other features and advantages of this invention will become apparent from the following detailed description of the various aspects of the invention taken in conjunction with the appended claims and the accompanying drawings.

### BRIEF DESCRIPTION OF THE DRAWINGS

The present invention will hereinafter be described in conjunction with the following drawing figures, wherein like numerals denote like elements, and:

FIG. 1 depicts possible routes for dual tone patterning a photoresist made from an embodiment of the inventive photoresist composition.

FIGS. 2A-D show physical characterization of an embodiment of the inventive nanoparticle. In particular, charts are provided showing results from, for FIG. 2A, DLS measurement of particle size, for FIG. 2B, infrared spectroscopy showing the characteristic absorption peaks, for FIG. 2C, TGA showing mass loss as a function of temperature, and for FIG. 2D, XPS spectroscopy on HfO2-benzoate film showing the atomic compositions.

FIG. 3 is a simplified schematic illustration of an embodiment of the inventive nanoparticle, and a resist film deposited by spin-coating a photoresist composition comprising the nanoparticles and a photoacid generator.

FIGS. 4A-B are images of line-space and contact patterns obtained at 50 mJ/cm2 DUV exposure (248 nm wavelength). FIG. 4A shows 500 nm patterns, and FIG. 4B shows 225 nm patterns.

FIG. 5 shows results of dissolution testing of non-limiting suitable organic solvents for developing patterned HfO₂-benzoate films made using an embodiment of the inventive photoresist composition. Representative micron-scale patterns developed with the respective solvents are shown as inserts.

FIG. 6 shows results of an XRD study on a HfO2-benzoate embodiment of the inventive nanoparticle (I), and also on a spin coated nanoparticle film (II) made using a photoresist composition according to the present invention.

FIG. 7 shows line-space patterns obtained at EUV exposure (13.5 nm wavelength) for a film made from an embodiment of the inventive photoresist composition.

FIG. 8 illustrates a positive and negative tone patterning mechanism for photoresists made using the inventive photoresist composition.

FIG. 9 depicts EUV patterning results using negative tone development on resists made from embodiments of the inventive photoresist composition.

FIGS. 10A and 10B show patterning results from additional testing on photoresists comprising nanoparticles.

FIGS. 11A and 11B show patterning results from additional testing on photoresists made using embodiments of the inventive photoresist composition.

### DETAILED DESCRIPTION OF THE INVENTION

Aspects of the present invention and certain features, advantages, and details thereof, are explained more fully below, and references are made to the non-limiting embodiments illustrated in the accompanying drawings (which are not necessarily drawn to scale). Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure.

As used herein, the following definitions shall apply unless otherwise indicated. For purposes of this invention, the chemical elements are identified in accordance with the Periodic Table of the Elements, CAS version, Handbook of Chemistry and Physics, 75th Ed. Additionally, general principles of organic chemistry are described in “Organic Chemistry”, Thomas Sorrell, University Science Books, Sausalito: 1999, and “March's Advanced Organic Chemistry”, 5th Ed., Ed.: Smith, M. B. and March, J., John Wiley & Sons, New York: 2001.

The term “hydrocarbyl” is a generic term encompassing C₁-C₁₀ aliphatic, alicyclic and aromatic groups having an all-carbon backbone, except where otherwise stated. “C.” defines the number (n) of carbon atoms in a group. Examples of hydrocarbyl groups include alkyl, cycloalkyl, alkenyl, cycloalkenyl, alkynyl, aryl, cycloalkylalkyl, cycloalkenylalkyl, and carbocyclic aralkyl, aralkenyl and aralkynyl groups. Within the sub-set of hydrocarbyl groups are those having 1 to 8 carbon atoms, examples including C₁₋₆ hydrocarbyl groups, such as C₁₋₄ hydrocarbyl groups (e.g., C₁₋₃ hydrocarbyl groups or C₁₋₂ hydrocarbyl groups). Specific examples of hydrocarbyl groups include any individual value or combination of values selected from C₁, C₂, C₃, C₄, C₅, C₆, C₇, C₈, C₉, and C₁₀, hydrocarbyl groups. The groups —CH₃, —CH₂CH₂, —CH(CH₃)₂, —C(CH₃)₃, and phenyl are non-limiting examples of specific hydrocarbyl groups. Hydrocarbyl includes any substituent comprised of hydrogen and carbon as the only elemental constituents.

The term “alkyl” covers both straight chain and branched hydrocarbon structures and combinations thereof. Examples of alkyl groups include methyl, ethyl, propyl, isopropyl, n-butyl, isobutyl, tert-butyl, n-pentyl, 2-pentyl, 3-pentyl, 2-methyl butyl, 3-methyl butyl, and n-hexyl and its isomers. Within the sub-set of alkyl groups are those having 1 to 8 carbon atoms, particular examples being C₁₋₆ alkyl groups, such as C₁₋₄ alkyl groups (e.g. C₁₋₃ alkyl groups or C₁₋₂ alkyl groups).

Examples of cycloalkyl groups are those derived from cyclopropane, cyclobutane, cyclopentane, cyclohexane and cycloheptane. Within the sub-set of cycloalkyl groups are cycloalkyl groups having from 3 to 8 carbon atoms, particular examples being C₃₋₆ cycloalkyl groups. Cycloalkyl, if not otherwise limited, refers to monocycles, bicycles and polycycles.

Examples of alkenyl groups include, but are not limited to, ethenyl(vinyl), 1-propenyl, 2-propenyl(allyl), isopropenyl, butenyl, buta-1,4-dienyl, pentenyl, and hexenyl. Within the sub-set of alkenyl groups are those having 2 to 8 carbon atoms, particular examples being C₂₋₆ alkenyl groups, such as C₂₋₄ alkenyl groups.

Examples of cycloalkenyl groups include, but are not limited to, cyclopropenyl, cyclobutenyl, cyclopentenyl, cyclopentadienyl and cyclohexenyl. Within the sub-set of cycloalkenyl groups are those having from 3 to 8 carbon atoms, for example, C₃₋₆ cycloalkenyl groups.

Examples of alkynyl groups include, but are not limited to, ethynyl and 2-propynyl (propargyl) groups. Within the sub-set of alkynyl groups are those having 2 to 8 carbon atoms, particular examples being C₂₋₆ alkynyl groups, such as C₂₋₄ alkynyl groups.

Examples of aryl groups, which are defined below, include phenyl and naphthyl groups.

References to “carbocyclic” and “heterocyclic” groups as used herein shall, unless the context indicates otherwise, include both aromatic and non-aromatic ring systems. Thus, for example, the term “carbocyclic and heterocyclic groups” includes within its scope aromatic, non-aromatic, unsaturated, partially saturated and fully saturated carbocyclic and heterocyclic ring systems. In general, such groups may be monocyclic for bicyclic and may contain, for example, 3 to 12 ring members, more usually 5 to 10 ring members. Examples of monocyclic groups are groups containing 3, 4, 5, 6, 7, and 8 ring members, more usually 3 to 7, and preferably 5 or 6 ring members. Examples of bicyclic groups are those containing 8, 9, 10, 11 and 12 ring members, and more usually 9 or 10 ring members.

The term “hydrocarbyloxy” refers to a hydrocarbyl group attached to the parent structure through an oxygen. Examples of hydrocarbyloxy groups include saturated hydrocarbyloxy such as alkoxy (e.g. C₁₋₆ alkoxy, more usually C₁₋₄ alkoxy such as ethoxy and methoxy, particularly methoxy), cycloalkoxy (e.g. C₃₋₆ cycloalkoxy such as cyclopropyloxy, cyclobutyloxy, cyclopentyloxy and cyclohexyloxy) and cycloalkyalkoxy (e.g. C₃₋₆ cycloalkyl-C₁₋₂ alkoxy such as cyclopropylmethoxy). Specific non-limiting examples include —OCH₃, —OCH₂CH₃, —O(CH₂) ₂CH₃, —OCH(CH₃)₂, —13 O(CH₂)₃CH₃, —O(CH₂) ₄CH₃, and phenoxy. For the purpose of this application, alkoxy includes methylenedioxy and ethylenedioxy.

Unless otherwise specified, “acyl” refers to formyl and to groups of 1, 2, 3, 4, 5, 6, 7, 8, 9, and 10 carbon atoms of a straight, branched, cyclic configuration, saturated, unsaturated and aromatic and combinations thereof, attached to the parent structure through a carbonyl functionality. One or more carbons in the acyl residue may be replaced by nitrogen, oxygen or sulfur as long as the point of attachment to the parent remains at the carbonyl. Examples include acetyl, benzoyl, propionyl, isobutyryl, t-butoxycarbonyl, benzyloxycarbonyl and the like. A subset of acyl is C₁-C₄ acyl. The double bonded oxygen, when referred to as a substituent itself is called “oxo”. An example of an acyl group is —COCH₃.

Unless otherwise specified, “aryl” and “heteroaryl” mean (i) a phenyl group (or benzene) or a monocyclic 5- or 6-membered heteroaromatic ring containing 1-4 heteroatoms independently selected from O, N, and S; (ii) a bicyclic 9- or 10-membered aromatic or heteroaromatic ring system containing 0-4 heteroatoms independently selected from O, N, and S; or (iii) a tricyclic 13- or 14-membered aromatic or heteroaromatic ring system containing 0-5 heteroatoms independently selected from O, N, and S. The aromatic 6- to 14-membered carbocyclic rings include, e.g., benzene, naphthalene, indane, tetralin, and fluorene and the 5- to 10-membered aromatic heterocyclic rings include, e.g., imidazole, pyridine, indole, thiophene, benzopyranone, thiazole, furan, benzimidazole, quinoline, isoquinoline, quinoxaline, pyrimidine, pyrazine, tetrazole and pyrazole. As used herein aryl and heteroaryl refer to residues in which one or more rings are aromatic, but not all need be.

The terms “halohydrocarbyl” and “halohydrocarbyloxy” mean hydrocarbyl or hydrocarbyloxy, respectively, substituted with one or more halogen atoms. Subsets include haloC₁₋₈hydrocarbyl and haloC₁₋₈hydrocarbyloxy, which are groups having 1-8 carbon atoms. Haloalkyl and haloalkoxy are subsets of halohydrocarbyl and halohydrocarbyloxy, respectively. Examples of halohydrocarbyl and halohydrocarbyloxy groups include —CF₃ and —OCF₃, respectively.

The term “hydrocarbyloxycarbonyl” means a —C(O)hydrocarbyloxy group. An example is —C(O)—O—CH₂CH₃.

The term “hydrocarbylcarboxy” means a —OC(O)hydrocarbyl group. An example is —OC(O)CH₃. C₁₋₈ hydrocarbylcarboxy is a particular subset of hydrocarbylcarboxy.

The term “hydrocarbylthio” means to a hydrocarbyl group attached to a parent structure via a sulfur atom. A subset is C₁₋₈ hydrocarbylthio. Examples of C₁₋₈ hydrocarbylthio groups include —SCH₃, —SCH₂CH₃, and —SCH(CH₃)₂.

The term “hydrocarbylsulfinyl” means a —SOhydrocarbyl group. A subset is C₁₋₈ hydrocarbylsulfinyl. An example is —SOCH₃.

The term “hydrocarbylsulfonyl” means a —SO₂hydrocarbyl group. A subset is C₁₋₈ hydrocarbylsulfonyl. An example is —SO₂CH₃.

The term “acetamide” means a —NHC(O)CH₃ group.

The term “aminosulfonyl” means a —SO₂NH₂ group.

The term “halogen” means fluorine, chlorine, bromine or iodine. In one embodiment, halogen may be fluorine or chlorine.

The term “carboxylate” refers to a dissociated acid. Carboxylates are monovalent anions having the formula RCOO⁻.

Substituents (e.g. Rⁿ) are generally defined when introduced and retain that definition throughout the specification and in all independent claims.

Although this invention is susceptible to embodiment in many different forms, certain embodiments of the invention are shown and described. It should be understood, however, that the present disclosure is to be considered as an exemplification of the principles of this invention and is not intended to limit the invention to the embodiments illustrated.

In a first aspect, the invention relates to a nanoparticle. The nanoparticle may interchangeably be referred to as a nanoparticle, a metal oxide nanoparticle, or a hybrid metal oxide nanoparticle (on account of its architecture, which includes both core and coating/shell).

The inventive nanoparticles include a core, which comprises a Group 4 metal oxide, and a coating (which may also and interchangeably be referred to as a shell). The coating surrounds the core, and includes one or more ligands selected from an organic acid according to Formula (I):

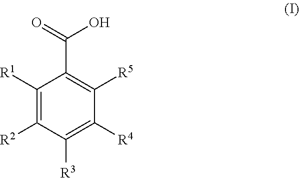

and a carboxylate thereof, wherein R¹, R², R³, R⁴, and R⁵ are each individually selected from hydrogen, C₁₋₈hydrocarbyl, halogen, hydroxyl, acyl, C₁₋₈hydrocarbylcarboxy, C₁₋₈ hydrocarbyloxy, C₁₋₈ hydrocarbyloxycarbonyl, carboxy, haloC₁₋₈hydrocarbyl, C₁₋₈ hydrocarbylthio, mercapto, cyano, thiocyanate, C₁₋₈ hydrocarbylsulfinyl, C₁₋₈ hydrocarbylsulfonyl, aminosulfonyl, amino, nitro, and acetamide, or two adjacent R¹-R⁵ groups, together with the carbon atoms to which they are attached, may form a 4-, 5- or 6-membered carbocyclic ring.

As used herein, when a Cₙ₋ₙ′group (e.g., a Cₙ₋ₙ′ hydrocarbyl group) is recited, whether on its own or as part of another group (e.g., haloCₙ₋ₙ′hydrocarbyl), it is intended that the recitation “C.ₙ₋ₙ′” includes all numbers and subranges falling within the n-n′ range. For example, where C₁₋₈ is recited, the recitation is intended to be shorthand, as if C₁, C₂, C₃, C₄, C₅, C₆, C₇, and C₈ were fully set forth. As further example, the term C₁₋₈ is intended to include all subranges therein, including, for example, C₁₋₆, C₁₋₄, C₁₋₃, C₂₋₆, etc.

Examples of embodiments where two adjacent R¹-R⁵ groups, together with the carbon atoms to which they are attached, form a 4-, 5- or 6-membered carbocyclic ring, include where two R groups, taken together, are —(CH₂)₂—, —(CH₂)₃—, or —(CH₂) ₄—, so as to form, together with the benzoic acid benzene ring, a bicyclic 1,2-dihydrocyclobutabenzene, 2,3-dihydro-1H-indene, or 1,2,3,4-tetrahydronaphthalene core.

In some embodiments where two adjacent R¹-R⁵ groups, together with the carbon atoms to which they are attached, form a 4-, 5- or 6-membered carbocyclic ring, the two adjacent R¹-R⁵ groups are R³ and R⁴. In some embodiments, the two adjacent R¹-R⁵ groups are R⁴ and R⁵. In some embodiments, the two adjacent R¹-R⁵ groups are R² and R³. In some embodiments, the two adjacent R¹-R⁵ groups are R¹ and R².

In some embodiments, R¹, R², R³, R⁴, and R⁵ are each individually selected from H, F, Cl, Br, —OH, —CH₃, —CH₂CH₂, —CH(CH₃)₂, —C(CH₃)₃, phenyl, —COCH₃, —OC(O)CH₃, —OCH₃, —OCH₂CH₃, O(CH₂) ₂CH₃, OCH(CH₃)₂, —O(CH₂)₃CH₃, —O(CH₂) ₄CH₃, phenoxy, —C(O)-O—CH₂CH₃, —C(O)OH, —CF₃, —OCF₃, —SCH₃, —SCH₂CH₃, —SCH(CH₃)₂, —SH, —CN, —SCN, —SOCH₃, —SO₂CH₃, —SO₂NH₂, —NH₂, —NO₂, and —NHC(O)CH₃.

In some embodiments, R¹, R², R³, R⁴, and R⁵ are individually selected from H, —F, —CH₃, —NH₂, —OH, —NO₂, and —CF₃.

In some embodiments, R¹, R², R³, R⁴, and R⁵ are all hydrogen.

In some embodiments, the benzene ring in Formula (I) has one non-hydrogen substituent (i.e., one of R¹, R², R³, R⁴, and R⁵ is other than hydrogen, and the remaining R¹-R⁵ are hydrogen). In some embodiments, the benzene ring in Formula (I) has one two non-hydrogen substituents. In some embodiments, the benzene ring in Formula (I) has one three non-hydrogen substituents. In some embodiments, the benzene ring in Formula (I) has four non-hydrogen substituents. In some embodiments, all of R¹-R⁵ are other than hydrogen.

In some embodiments, the ligand of Formula (I) or carboxylate thereof may be ortho-, meta-, or para-substituted (i.e., may have non-hydrogen substituents in the ortho, meta, or para positions).

In some embodiments, the ligand is an organic acid of Formula (I). In some embodiments, the ligand is a carboxylate of the organic acid of Formula (I). In some embodiments, the nanoparticle comprises both an organic acid according to Formula (I) and a carboxylate thereof

In some embodiments, the ligand is benzoic acid or a carboxylate thereof. In such embodiments, one or both of the acid and the carboxylate thereof may be present.

The core of the inventive nanoparticle comprises a Group 4 metal oxide. In some embodiments, the core comprises more than one Group 4 metal oxide (e.g., 2 metal oxides, 3 metal oxides, etc.).

The Group 4 metal oxide in the nanoparticle core may comprise titanium (Ti), zirconium (Zr), and/or hafnium (Hf). In some embodiments, the core comprises hafnium oxide (e.g., HfO₂). In some embodiments, the core comprises zirconium oxide (e.g., ZrO₂). In some embodiments, the core comprises titanium oxide (e.g., TiO₂).

In some embodiments, the nanoparticle of the invention has a diameter of about 1 to 12 nm (e.g., 1, 2, 3, 4, 5, 6, 7, 8, 9, 10, 11, or 12 nm), including any and all ranges and subranges therein (e.g., 1-4 nm, 2.5-5 nm, 2-4 nm, etc.)

In some embodiments, the nanoparticle of the invention comprises 35 wt % to 75 wt % (e.g., 35, 40, 45, 50, 55, 60, 65, 70, 75 wt %, etc.) core (i.e., the core constitutes 35-75 wt % of the entire nanoparticle), including any and all ranges and subranges therein. In some embodiments, the nanoparticle comprises 35-75 wt % titanium oxide, zirconium oxide, or hafnium oxide, or combinations thereof

In some embodiments, the nanoparticle of the invention comprises 25 wt % to 65 wt % (e.g., 25, 30, 35, 40, 45, 50, 55, 60, 65 wt %, etc.) coating (i.e., the coating constitutes 35-75 wt % of the entire nanoparticle), including any and all ranges and subranges therein. In some embodiments, the nanoparticle comprises 25-65 wt % organic ligand.

In some embodiments, the inventive nanoparticle comprises TiO₂, ZrO₂, or HfO₂ (meaning at least one of the oxides) and the ligand is benzoic acid or a carboxylate thereof

In some embodiments, the invention provides a photoresist composition that comprises the nanoparticle according to claim 1.

In some embodiments, the invention provides a photoresist film (e.g., a film that has been deposited by, for example, spin-coating) that comprises the nanoparticle according to claim 1.

In some embodiments, the invention provides photoresist compositions and photoresist films that comprise a nanoparticle according to claim 1 and a photoacid generator. Photoacid generators are discussed below. In some embodiments, the photoacid generator is selected from N-hydroxynaphthalimide triflate, triphenylsulphonium triflate, and triphenylsulphonium perfluoro-1-butanesulphonate.

In another aspect, the invention relates to a photoresist composition comprising a nanoparticle and a photoacid generator. The nanoparticle comprises a core, which comprises a Group 4 metal oxide, and a coating surrounding the core. The coating comprises a ligand selected from an acid and a carboxylate of the acid. The photoacid generator is one that is capable, upon photodecomposition, of generating an acid having a pKa lower than the pKa of the ligand acid.

As used herein, “pKa of the ligand acid” (pKa_{LA}) refers to the pKa of the ligand acid (if the nanoparticle coating comprises a ligand that is an acid), or to the pKa of the acid form of the carboxylate ligand (if the nanoparticle coating comprises a ligand that is a carboxylate). For example, if the nanoparticle coating comprises, as a ligand, RCOO⁻, then “pKa of the ligand acid,” or “pKa_{LA},” would refer to the pKa of the corresponding acid, RCOOH, and the photoacid generator in the photoresist composition would be capable of generating an acid having a pKa lower than the pKa of RCOOH. Thus, the pKa_{LA} for an acid and a carboxylate thereof, RCOOH and RCOO⁻, respectively, is the same.

A photoacid generator is a compound that can be decomposed by light or radiation to generate an acid. Various photoacid generators are known in the art, and may be used in the inventive photoresist compositions, provided that the pKa of the acid that the photoacid generator is capable of generating (pKa_{PAG}) is lower than the pKa of the ligand acid (pKa_{LA}).

Where more than one ligand is present in the nanoparticle coating (other than the situation where two ligands are present, one being an acid and the other being a carboxylate of that acid), the photoacid generator is capable of generating an acid having a pKa (pKa_{PAG}) that is lower than at least the highestlowest pKa_{PAG}. In some embodiments, where more than one ligand is present in the nanoparticle coating, the photoacid generator is capable of generating an acid having a pKa (pKa_{PAG}) that is lower than all of the pKa's of the ligand acids.

In some embodiments, the photoacid generator is ionic. In some embodiments, the photoacid generator is non-ionic.

In some embodiments, the amount of photoacid generator in the photoresist composition is 0.5 to 10 wt % photoacid generator per gram of nanoparticle (e.g., 0.5, 1, 2, 3, 4, 5, 6, 7, 8, 9, or 10 wt %, including any and all ranges and subranges therein (e.g., 0.5 to 8 wt %, 1 to 7 wt %, etc.).

Examples of photoacid generators that may be used in the invention include, without limitation, Bis(4-tert-butylphenyl)iodonium perfluoro-1-butanesulfonate, Bis(4-tert-butylphenyl)iodonium p-toluenesulfonate, Bis(4-tert-butylphenyl)iodonium triflate, Boc-methoxyphenyldiphenylsulfonium triflate, (4-Bromophenyl)diphenylsulfonium triflate, (tert-Butoxycarbonylmethoxynaphthyl)-diphenylsulfonium triflate, (4-tert-Butylphenyl)diphenylsulfonium triflate, Diphenyliodonium hexafluorophosphate, Diphenyliodonium nitrate, Diphenyliodonium perfluoro-1-butanesulfonate, Diphenyliodonium p-toluenesulfonate, Diphenyliodonium triflate, (4-Fluorophenyl)diphenylsulfonium triflate, N-Hydroxynaphthalimide triflate, N-Hydroxy-5-norbornene-2,3-dicarboximide perfluoro-1-butanesulfonate, (4-Iodophenyl)diphenylsulfonium triflate, (4-Methoxyphenyl)diphenylsulfonium triflate, 2-(4-Methoxystyryl)-4,6-bis(trichloromethyl)-1,3,5-triazine, (4-Methylphenyl)diphenylsulfonium triflate, (4-Methylthiophenyl)methyl phenyl sulfonium triflate, (4-Phenoxyphenyl)diphenylsulfonium triflate, (4-Phenylthiophenyl)diphenylsulfonium triflate, Triarylsulfonium hexafluorophosphate salts, Triphenylsulfonium perfluoro-1-butanesufonate, Triphenylsulfonium triflate, Tris(4-tert-butylphenyl)sulfonium perfluoro-1-butanesulfonate, and Tris(4-tert-butylphenyl)sulfonium triflate.

In some embodiments the photoacid generator is selected from N-hydroxynaphthalimide triflate (also known as 1,3-dioxo-1H-benzo[de]isoquinolin-2(3H)-yl trifluoroMethanesulfonate), triphenylsulphonium triflate, and triphenylsulphonium perfluoro-1-butanesulphonate.

The photoresist compositions of the present invention include a nanoparticle that comprises: a core comprising a Group 4 metal oxide; and a coating surrounding the core, said coating comprising a ligand selected from an acid and a carboxylate thereof

Methods for making nanoparticles are known in art, and are described, for example, in U.S. Pat. No. 8,124,230.

The core of the nanoparticle of the inventive photoresist composition may be any core as described above in connection with the inventive nanoparticle.

The ligand acid or carboxylate thereof in the nanoparticle coating surrounding the core may be any acid or carboxylate thereof, provided that pKa_{LA}>pKa_{PAG}.

Certain non-limiting ligands that may be used in the nanoparticles of the inventive photoresist composition can be found, for example, in U.S. Pat. No. 8,124,230.

In some embodiments, the photoresist composition comprises a nanoparticle having a coating that comprises a ligand selected from an organic acid according to Formula (I):

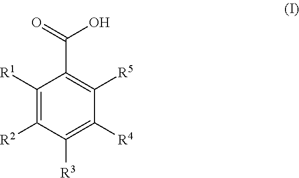

and a carboxylate thereof,
wherein R¹, R², R³, R⁴, and R⁵ are individually selected from hydrogen, C₁₋₈hydrocarbyl, halogen, hydroxyl, acyl, C₁₋₈hydrocarbylcarboxy, C₁₋₈ hydrocarbyloxy, C₁₋₈ hydrocarbyloxycarbonyl, carboxy, haloC₁₋₈hydrocarbyl, C₁₋₈ hydrocarbylthio, mercapto, cyano, thiocyanate, C₁₋₈ hydrocarbylsulfinyl, C₁₋₈ hydrocarbylsulfonyl, aminosulfonyl, amino, nitro, and acetamide,
or two adjacent R¹-R⁵ groups, together with the carbon atoms to which they are attached, may form a 5- or 6-membered carbocyclic ring.

In some embodiments, the inventive photoresist composition comprises the inventive nanoparticle described in the first aspect of the present invention.

In some embodiments, the photoresist composition comprises an organic solvent. In some embodiments, the organic solvent may be propylene glycol monomethyl ether acetate (PGMEA).

In some embodiments, the invention provides a photoresist composition comprising a nanoparticle that includes a coating having a ligand selected from benzoic acid or a carboxylate thereof, methacrylic acid or a carboxylate thereof, or trans-2,3 dimethylacrylic acid or a carboxylate thereof

In some embodiments, the invention provides a photoresist composition comprising a nanoparticle that includes a coating having a ligand selected from methacrylic acid, trans-2,3-dimethylacrylic acid, ethylacrylic acid, propylacrylic acid and methylbutyric acid, and carboxylates thereof (i.e., carboxylates of any of the listed acids).

In some embodiments, the inventive photoresist composition is one that, upon being applied to a substrate, results in a photoresist film that can be patterning using EUV.

In some embodiments, the inventive photoresist composition is one that, upon being applied (e.g., spin-coated) to a substrate, results in a photoresist film capable of producing high resolution (e.g., 22-50 nm lines-space), and smooth patterns (LER ranging from 3-5 nm) under EUV exposures at comparatively lower doses (e.g., 0.8 mJ/cm2 to 17.5 mJ/cm2).

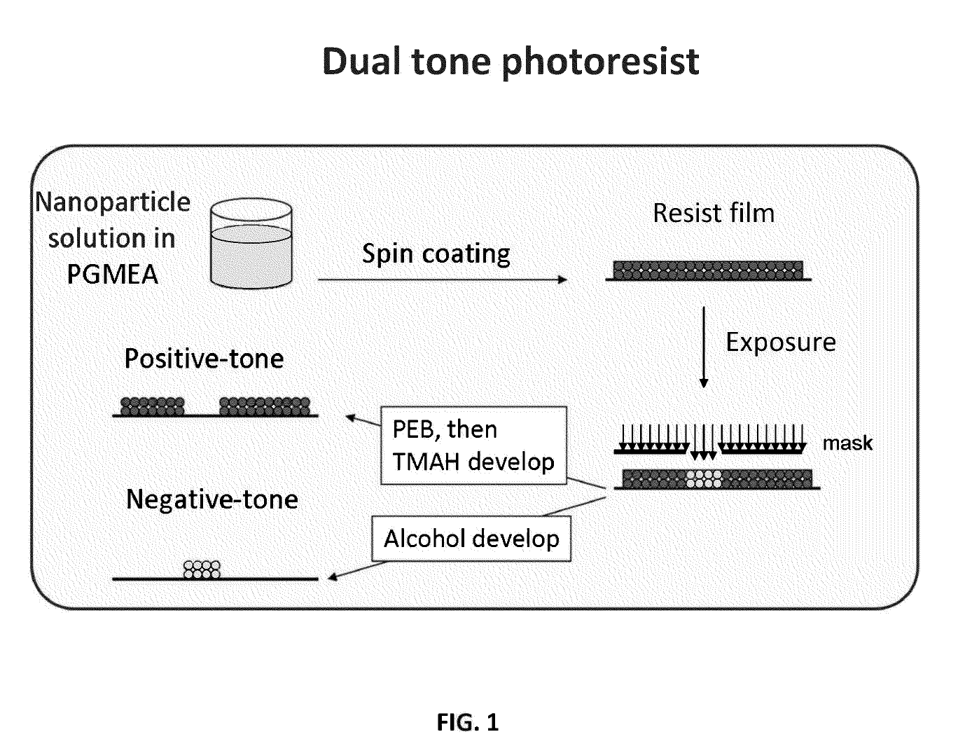

In some embodiments, the inventive photoresist composition is one that, upon being applied to a substrate, results in a photoresist film that is capable of dual-tone patterning (i.e., the resist can be used in positive or negative tone development). Positive and negative tone development techniques suitable for use in patterning a photoresist made from the inventive photoresist composition are well known in the art. FIG. 1 depicts possible routes for dual tone patterning a photoresist made from the inventive photoresist composition. In FIG. 1, the Nanoparticle solution in PGMEA corresponds to an embodiment of the photoresist composition according to the present invention.

In some embodiments, the photoresist compositions of the invention do not include a photoradical initiator.

In some embodiments, the photoresist compositions of the invention do not include a polymer that is sensitive to the photoacid generator (i.e., do not include a polymer that is sensitive to the acid that the photoacid generator is capable of generating).

In another aspect, the invention provides a method for patterning a substrate, said method comprising:
forming a photoresist by applying on a substrate a photoresist composition comprising:
   a nanoparticle comprising:
      a core comprising a Group 4 metal oxide; and
      a coating surrounding the core, said coating comprising a ligand selected from an acid and a carboxylate thereof; and
   a photoacid generator,
wherein said photoacid generator is capable, upon photodecomposition, of generating an acid having a pKa lower than the pKa of the ligand acid,
imagewise exposing a defined region of the applied composition; and
developing the photoresist using positive tone development or negative tone development.

In some embodiments, patterning methods applied to resists made from the inventive photoresist composition do not include an additional post exposure bake (PEB) to, for example, generate negative tone patterns.

### EXAMPLES

The invention will now be illustrated, but not limited, by reference to specific embodiments described in the following examples.

Synthesis of an Embodiment of the Inventive Nanoparticle —HfO₂ Core with Benzoate Ligand Coating:

Hafnium isopropoxide, benzoic acid and PGMEA were purchased from Sigma Aldrich. Solvents like THF and acetone were obtained from Fisher Scientific. A typical synthesis consists of reacting 3g of hafnium isopropoxide and 5g of benzoic acid dissolved in 20m1 of THF respectively. The reactants were stirred at 65° C. for 2 hours followed by addition of 2 ml of DI water, to initiate sol-gel reaction. After 18 hours of reaction time, the reaction mixture was precipitated and washed with a mixture of acetone/water (1:4, vol) and the nanoparticles were dried for 24 hours under vacuum.

The mild reaction conditions of sol-gel chemistry allowed for efficient incorporation of the organic moieties into the inorganic components. HfO₂-benzoate nanoparticles were isolated as white amorphous powders as confirmed from x-ray diffraction.

Nanoparticle characterization was done using zetasizer Nano-ZS, Q500 thermogravimetric analyzer, Nicolet iS10 spectrophotometer and SSX-100 XPS. The nanoparticle resists were subjected to UV exposure using the ABM contact aligner and a 300C DUV stepper at Cornell University, and an MET EUV exposure tool at LBNL. SEM images were obtained with the Zeiss Supra SEM at an accelerating voltage ranging from 0.5kV to lkV and 20 gm aperture.

The nanoparticles were easily dispersed in organic solvents like propylene glycol monomethyl ether acetate (PGMEA) at high loadings up to 50% (w/w).

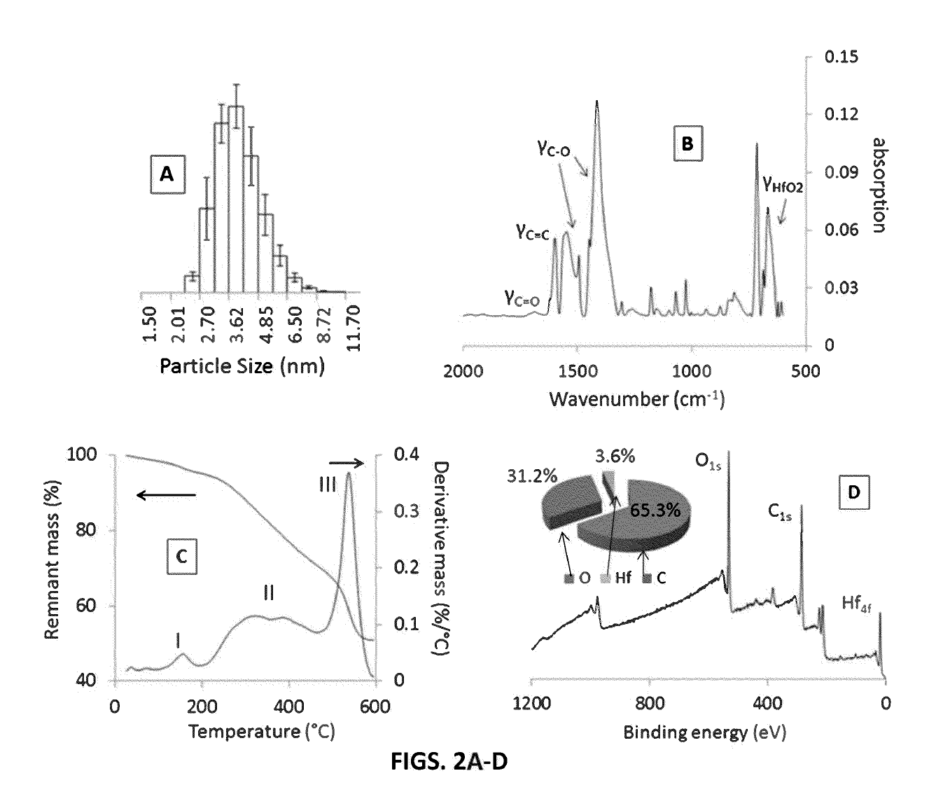

FIGS. 2A-D show physical characterization of the hybrid HfO₂-benzoate nanoparticles. In particular, charts are provided showing results from, for FIG. 2A, DLS measurement of particle size, for FIG. 2B, infrared spectroscopy showing the characteristic absorption peaks, for FIG. 2C, TGA showing mass loss as a function of temperature, and for FIG. 2D, XPS spectroscopy on HfO2-benzoate film showing the atomic compositions.

Nanoparticle particle size was determined by dynamic light scattering techniques (FIG. 2A), where an HfO₂-benzoate dispersion of 10 wt % in PGMEA was prepared for the measurements, giving an average particle size of 3.2 nm with a narrow size distribution. FTIR analysis on the as-prepared nanoparticle powder (FIG. 2B) shows the presence of asymmetric and symmetric absorption bands for benzoate moieties at 1410 cm⁻¹ and 1560 cm⁻¹ as well as a very weak absorption band at 1670 cm⁻¹ corresponding to the C═O group of the protonated ligand. A distinct peak at 1610 cm⁻¹ is observed due to strong absorption from the C=C groups of the benzoate moiety. Presence of a strong peak at 660 cm⁻¹ indicates the presence of Hf—O-Hf groups in the nanoparticle. Thermogravimetric analysis (TGA) was performed on the nanoparticles at a heating rate of 10° C/min where the total organic content was observed to be 49%. FIG. 2C shows the mass loss and the derivative mass loss as a function of temperature. Peak ‘a’ at 140° C. in FIG. 2C is attributed to the loss of crystal water followed by a broad peak ‘b’ at 300° C. due to dissociation of benzoate moieties into a solid organic residue and carbon dioxide. Finally, a sharp peak ‘c’ at 530° C. is due to decomposition of the solid organic residue. X-ray photoelectron spectroscopy study was performed on a nanoparticle film at 57° take-off angle and the spectrum is shown in FIG. 2D. Analysis of the spectrum shows the resist film to be comprised of 3.6% Hf, 31.2% 0 and 65.3% C. From calculations based on atomic composition and correlating them with mass loss results as obtained from TGA, it has been determined that each HfO₂ nanoparticle core is covered with ˜5 benzoate ligands at their surface.

Formation and Deposition of an Embodiment of the Inventive Photoresist:

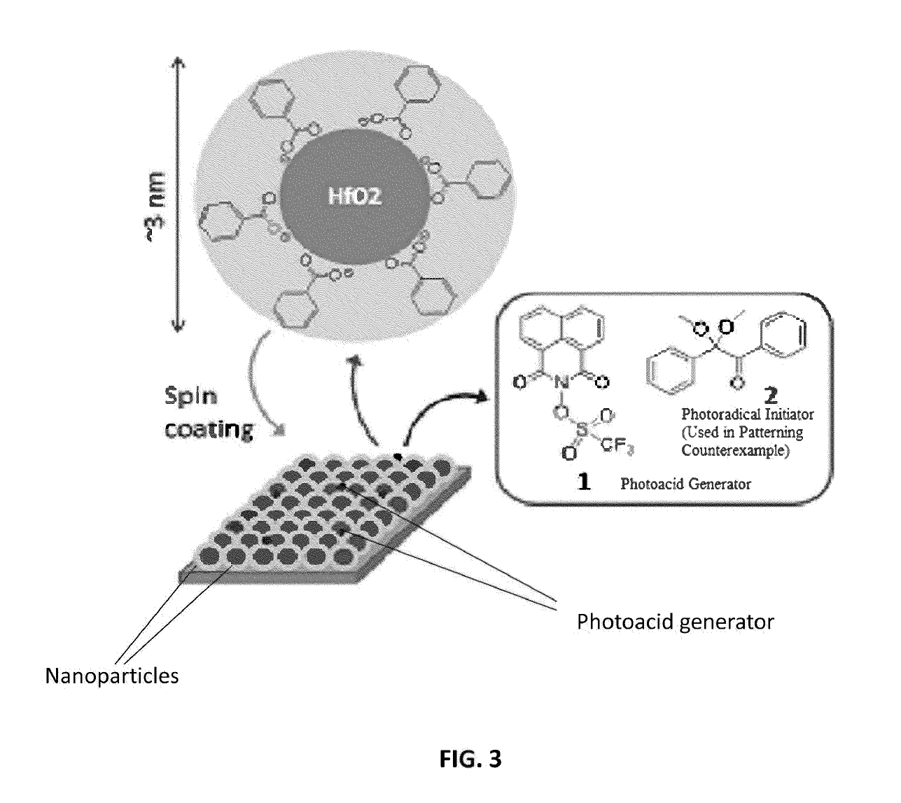

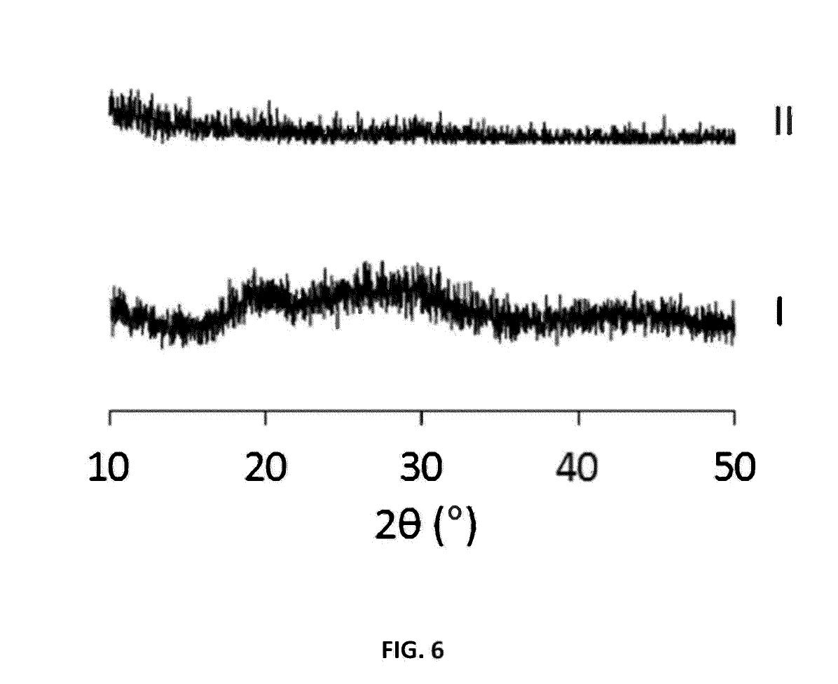

A photoresist composition was prepared by dispersing HfO₂-benzoate nanoparticles in PGMEA at 5-10 wt % of the final dispersion and adding a small amount (1-7 wt % per gram of nanoparticle) of a photoacid generator, N-hydroxynaphthalimide triflate. The hybrid nanoparticles were spin coated on bare silicon wafers using standard protocols as described in Krysak et al., Development of an inorganic nanoparticle photoresist for EUV, e-beam, and 193 nm lithography, Proceedings of SPIE 7972, (Pt. 1, Advances in Resist Materials and Processing Technology XXVIII), 2011, 7972, 79721C1-C6, and Trikeriotis et al., Development of an inorganic photoresist for DUV, EUV, and electron beam imaging, Proceedings of SPIE 7639, (Pt. 1, Advances in Resist Materials and Processing Technology XXVII), 2010, 7639, 76390E1-E10, forming uniform films without any crystalline domains (see FIG. 6). FIG. 3 is a simplified schematic illustration of a nanoparticle corresponding to the HfO₂-benzoate nanoparticles used, and a resist film deposited by spin-coating a photoresist composition comprising the nanoparticles and a photoacid generator 1.

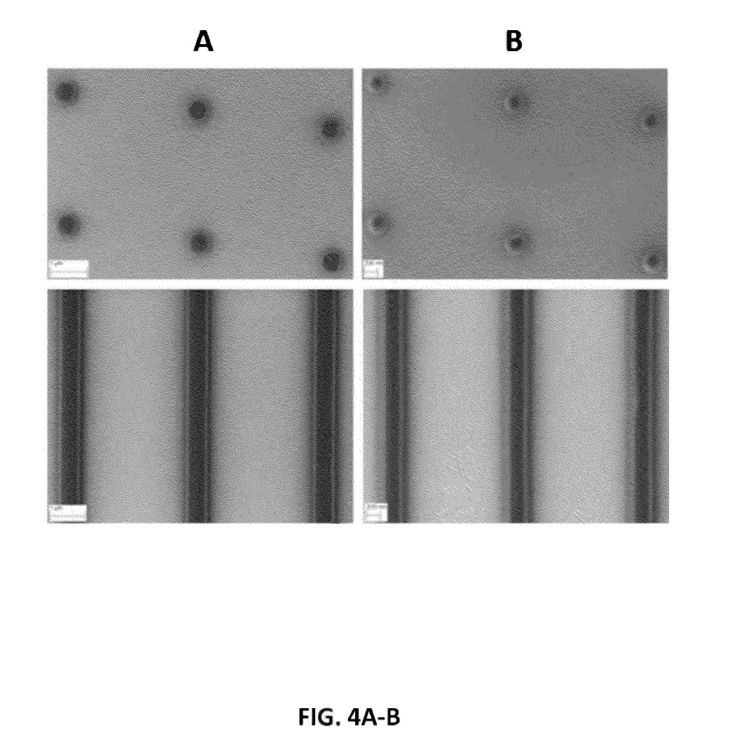

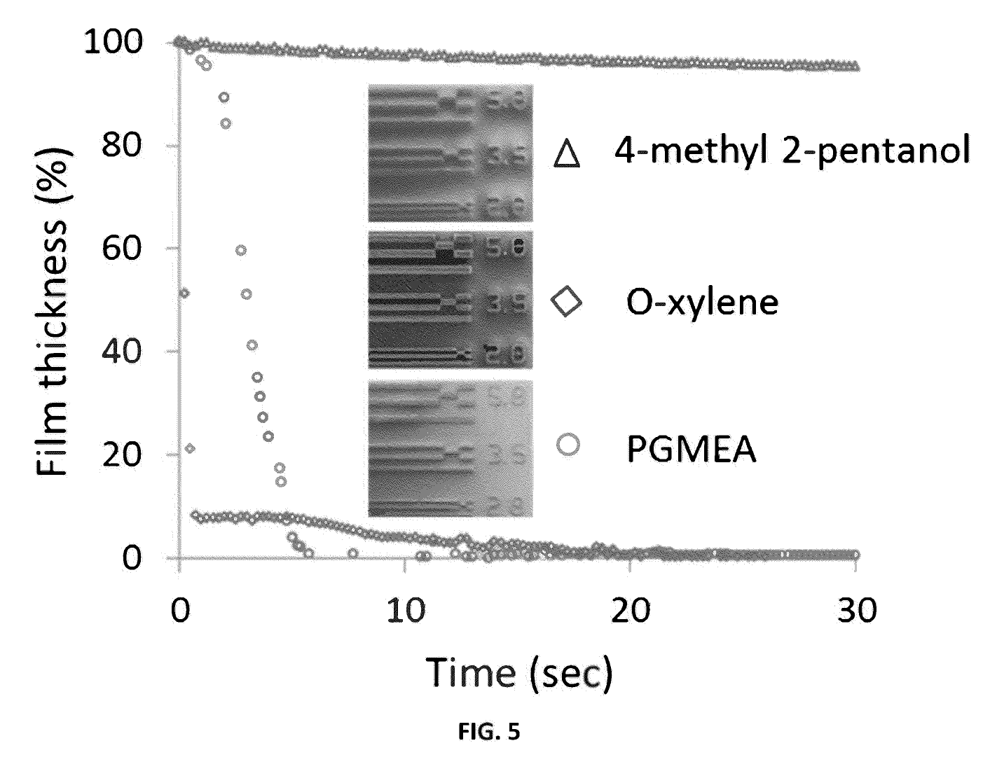

Nano-scale patterning ability of the HfO2-benzoate film was examined under deep ultraviolet (DUV) exposures using a 300C ASML stepper operating at 248 nm. FIGS. 4A-B are images of line-space and contact patterns obtained at 50 mJ/cm2 DUV exposure (248 nm wavelength). FIG. 4A shows 500 nm patterns, and FIG. 4B shows 225 nm patterns. As can be seen, in the presence of 1 wt % of the nonionic photoacid generator (N-hydroxynaphthalimide triflate), sharp line-space and contact negative tone patterns were obtained at a dose of 50 mJ/cm2 achieving resolution up to 225 nm. The exposed HfO2-benzoate resist films were developed in ortho-xylene, in which the nanoparticles had optimum dissolution behavior and produced excellent patterns. FIG. 5 shows results of dissolution testing of non-limiting suitable organic solvents for developing patterned HfO₂-benzoate films made using an embodiment of the inventive photoresist composition. Representative micron-scale patterns developed with the respective solvents are shown as inserts. FIG. 6 shows results of an XRD study on the as-prepared HfO2-benzoate nanoparticle (I), and also on the spin coated nanoparticle film (II) described below.

Patterning an Embodiment of the Inventive Photoresist

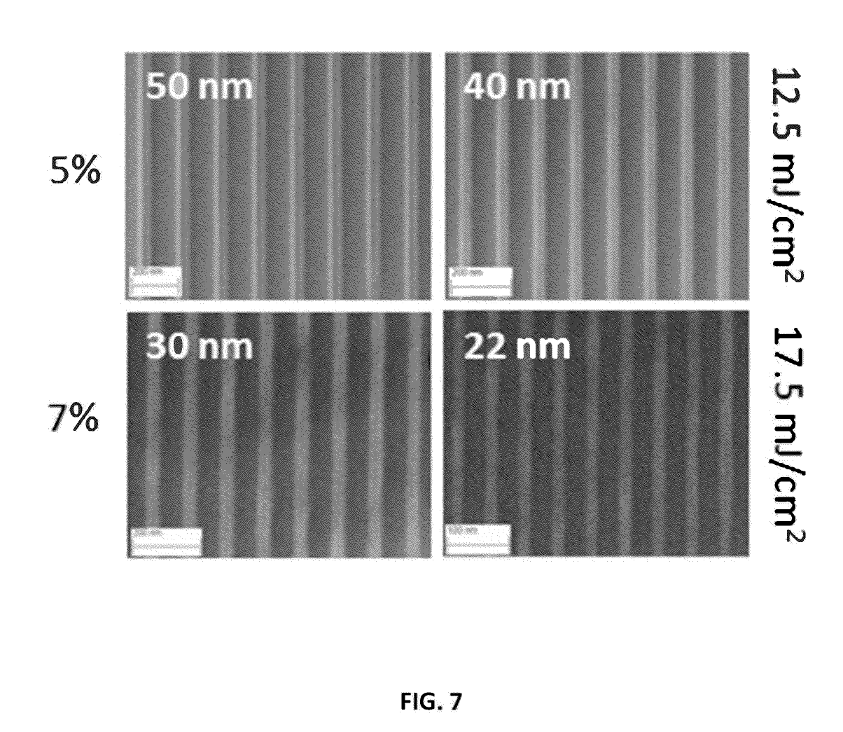

According to Moore's Law, the number of transistors that can be packed into an integrated circuit approximately doubles every two years, which stresses the importance of producing high resolution features in order to shrink down transistor dimensions. A significant improvement in the resolution of a patterned image can be obtained by reducing the wavelength of exposed radiation. As a result, higher resolution patterning of a HfO₂-benzoate photoresist composition was investigated under extreme ultraviolet (EUV) radiation (λ=13.5 nm) at the Center of X-Ray Optics, LBNL, to probe into sub-50 nm features. FIG. 7 shows resultant line-space patterns obtained at EUV exposure (13.5 nm wavelength). As shown, at 12.5 mJ/cm2 of EUV radiation, 50 nm and 40 nm lines-space patterns (1:1 pitch) were patterned on resist films having 5 wt % photoacid generator (N-hydroxynaphthalimide triflate). Higher resolution features of 30 nm and 22 nm lines were patterned at a PAG (N-hydroxynaphthalimide triflate) concentration of 7 wt % with 17.5 mJ/cm2 of EUV radiation.

Another notable aspect is that use of the HfO₂-benzoate photoacid generator-containing photoresist composition results in films/resists that produce very smooth patterns with line edge roughness (LER) ranging between 3-5 nm. Another study on metal oxide sulphate resists (Stowers et al., Directly patterned inorganic hardmask for EUV lithography. Proc. of SPIE, 2011; Vol. 7969) have produced 26 nm half pitch features at comparable LER values but at a EUV sensitivity >54 mJ/cm2, which is 3 times lower than the HfO₂-benzoate nanoparticle resist made with the photoresist composition according to the present invention. Another extensive study on commercial polymeric resists (Wallow et al., Evaluation of EUV resist materials for use at the 32 nm half-pitch node—art. no. 69211F., Emerging Lithographic Technologies Xii, Pts 1 and 2, 2008; Vol. 6921, pp F9211-F9211) with different line-space patterns have shown that at comparable LER, the resolution is restricted to 25 nm lines with an EUV dose to pattern ranging from 30-50 mJ/cm2. From another study (Petrillo et al., Are extreme ultraviolet resists ready for the 32 nm node? J. Vac. Sci. Technol. B, 2007, 25, (6), 2490-2495) on a wide range of ArF and KrF based commercially obtained DUV photoresists it was observed that at comparable resist sensitivity, the resolution was limited to 35 nm lines at comparable LER.

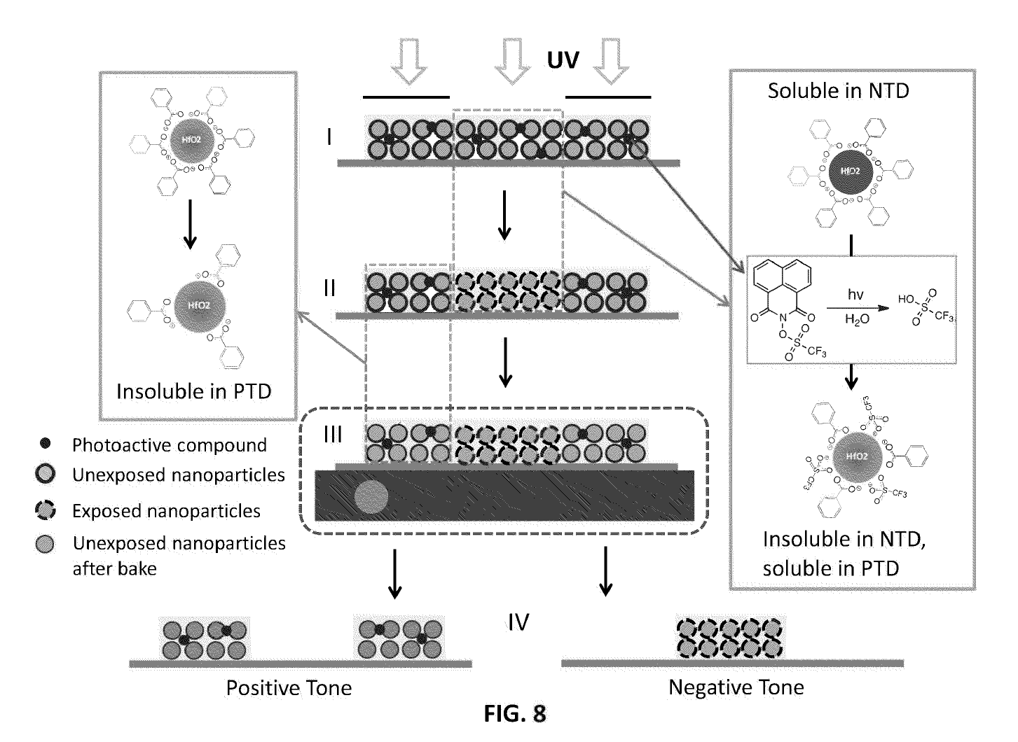

FIG. 8 illustrates a positive and negative tone patterning mechanism for the photoresists made from the inventive photoresist composition. Unlike conventional resists that undergo patterning by chemical amplification and deprotection reactions, this class of nanoparticle resists follow a non-chemically amplified route (Chakrabarty et al., Oxide nanoparticle EUV resists: toward understanding the mechanism of positive and negative tone patterning. Proc. SPIE 8679, Extreme Ultraviolet (EUV) Lithography IV, 867906 2013). Step I in FIG. 8 shows formation of a uniform resist film containing nanoparticles and photoacid generator (made from the inventive photoresist composition). The film is exposed to UV radiation via a photomask, which dissociates the photoacid generator to liberate a strong photoacid. In the depicted case, the photoacid generator liberates a highly acidic trifluorosulphonate acid, which has a very high binding affinity towards the metal oxide (Cardineau et al., Tightly-Bound Ligands for Hafnium Nanoparticle EUV Resists. In Extreme Ultraviolet, 2012; Vol. 8322). The photoacid displaces the weakly bound ligand (Step II in FIG. 8) from the nanoparticle shell and preferentially binds to the particle core, changing surface chemistry of the nanoparticles. Hence, in Step II, the exposed and unexposed regions of the resist have different nanoparticle chemistry as depicted in FIG. 8. Unlike conventional resists, the hybrid nanoparticle films do not require an additional post exposure bake (PEB) to generate negative tone patterns since it does not follow a chemically amplified route. Step III involves a post exposure bake (PEB) which is specific for positive tone patterning, wherein, the baking step eliminates a fraction of the surface ligand from the nanoparticles, making the unexposed regions insoluble in positive tone developers (PTD). Whereas, the exposed region which has a fraction of trifluorosulphonate ligand attached to the nanoparticle core remains insoluble in negative tone developers (NTD) but soluble in PTDs. This new mechanism wherein the nanoparticle films undergo dual tone patterning provides immense flexibility for tuning resist parameters in order to optimize lithographic performance.

Additional Patterning Testing

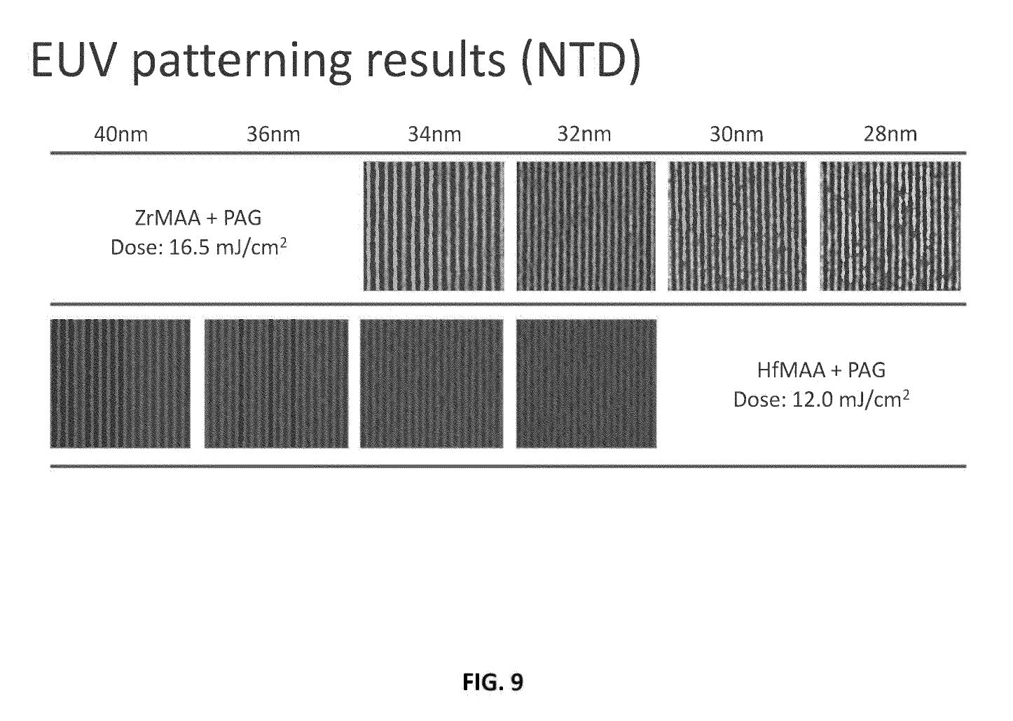

Additional testing was performed on various embodiments of the inventive nanoparticles, photoresist compositions, and resists made from the inventive photoresist compositions. FIG. 9 depicts EUV patterning results using negative tone development on resists made from embodiments of the inventive photoresist composition, one comprising hafnium oxide/methacrylic acid nanoparticles (HfMAA) and N-hydroxynaphthalimide triflate as a photoacid generator, the other comprising zirconium oxide/methacrylic acid nanoparticles (ZrMAA) and N-hydroxynaphthalimide triflate as a photoacid generator. Both resists were developed in 4-methyl-2-pentanol, and both resists were highly sensitive.

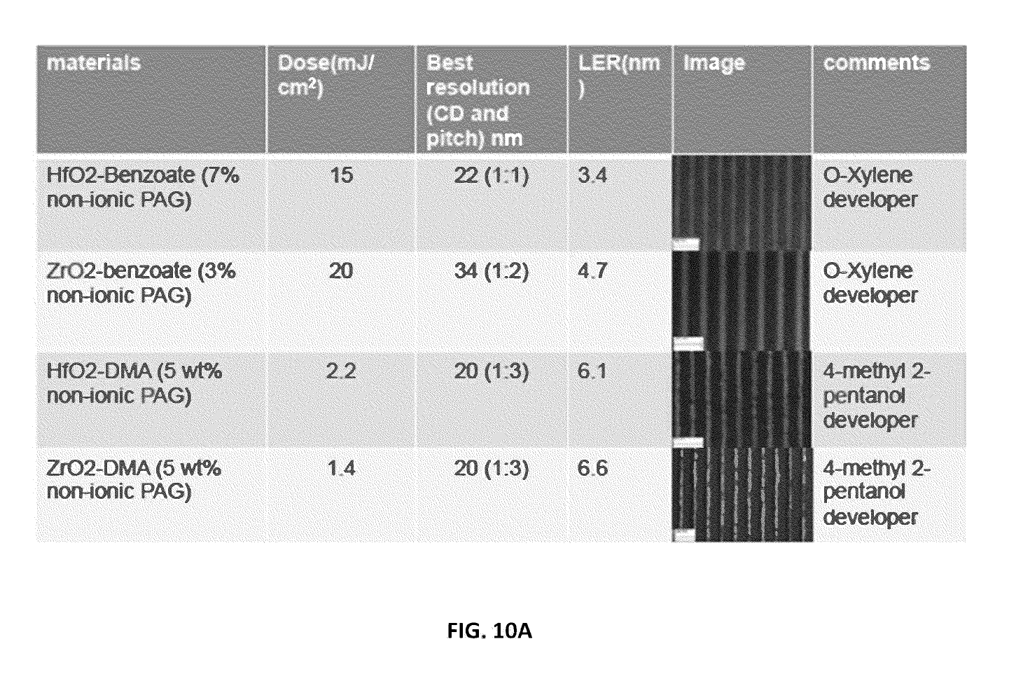

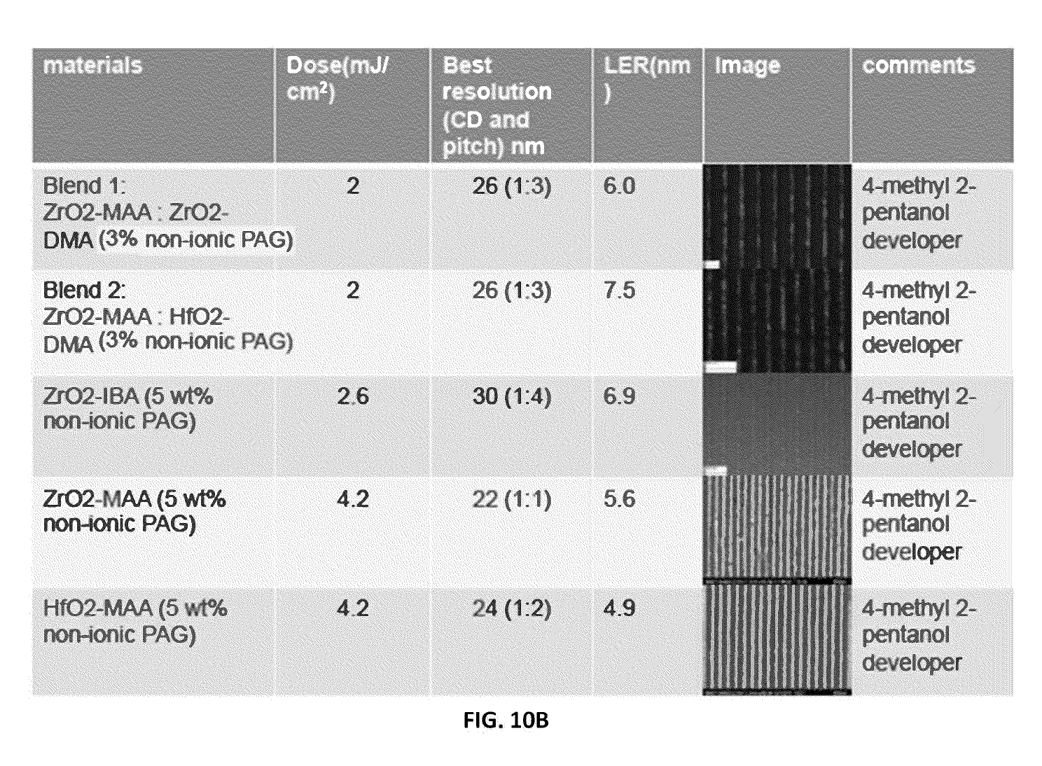

FIGS. 10A and 10B show patterning results from additional testing on photoresists made using embodiments of the inventive photoresist compositionc. The “non-ionic PAG” referred to in FIGS. 10A and 10B is N-hydroxynaphthalimide triflate.

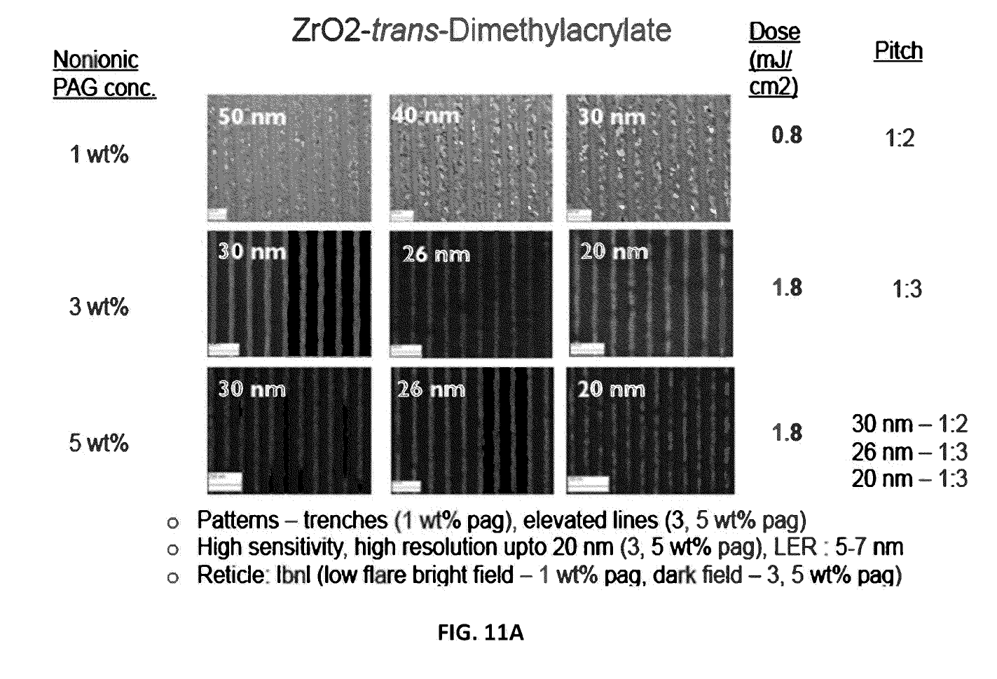

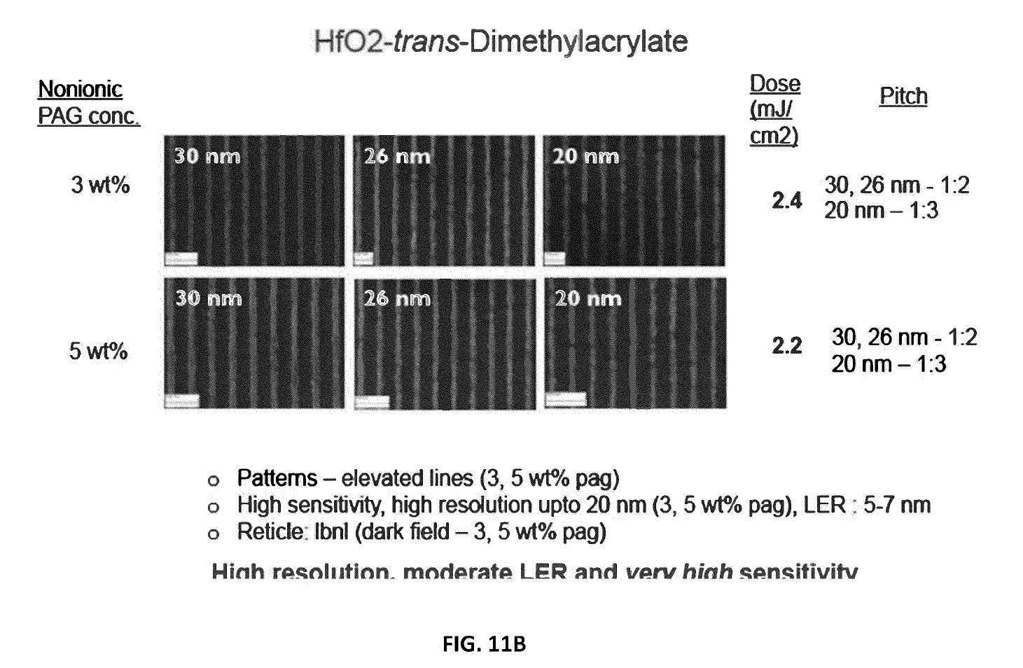

FIGS. 11A and 11B show patterning results from additional testing on photoresists made using embodiments of the inventive photoresist composition. FIG. 11A shows results for a resist comprising a photoacid generator (N-hydroxynaphthalimide triflate) and a nanoparticle having a core comprising zirconium dioxide and a coating comprising dimethylacrylate. FIG. 1 lB shows results for a resist comprising a photoacid generator (N-hydroxynaphthalimide triflate) and a nanoparticle having a core comprising hafnium(IV) oxide and a coating comprising dimethylacrylate.

Patterning Counterexample

As an additional confirmation for the ligand displacement mechanism described above, EUV exposure studies were performed with HfO₂-benzoate films in the presence of compound 2 (FIG. 3), which is a photoradical initiator, generating benzoate radicals upon UV exposure. Due to similar binding affinity between the nanoparticle ligand and the generated photoradical, ligand displacement did not occur. As a result, no observable patterns were obtained.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

As used herein, the terms “comprising” and “including” or grammatical variants thereof are to be taken as specifying the stated features, integers, steps or components but do not preclude the addition of one or more additional features, integers, steps, components or groups thereof. This term encompasses the terms “consisting of” and “consisting essentially of”.

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

All publications cited in this specification are herein incorporated by reference as if each individual publication were specifically and individually indicated to be incorporated by reference herein as though fully set forth.

Subject matter incorporated by reference is not considered to be an alternative to any claim limitations, unless otherwise explicitly indicated.

Where one or more ranges are referred to throughout this specification, each range is intended to be a shorthand format for presenting information, where the range is understood to encompass each discrete point within the range as if the same were fully set forth herein.

While several aspects and embodiments of the present invention have been described and depicted herein, alternative aspects and embodiments may be affected by those skilled in the art to accomplish the same objectives. Accordingly, this disclosure and the appended claims are intended to cover all such further and alternative aspects and embodiments as fall within the true spirit and scope of the invention.

1. A nanoparticle comprising:
a core comprising a Group 4 metal oxide; and
a coating surrounding the core, said coating comprising a ligand selected from an organic acid according to Formula (I): 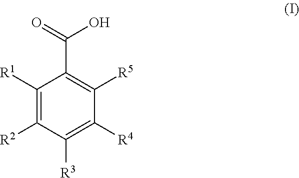
and a carboxylate thereof, wherein
R¹, R², R³, R⁴, and R⁵ are each individually selected from hydrogen, C₁₋₈ hydrocarbyl, halogen, hydroxyl, acyl, C₁₋₈ hydrocarbylcarboxy, C₁₋₈ hydrocarbyloxy, C₁₋₈ hydrocarbyloxycarbonyl, carboxy, haloC₁₋₈hydrocarbyl, C₁₋₈ hydrocarbylthio, mercapto, cyano, thiocyanate, C₁₋₈ hydrocarbylsulfinyl, C₁₋₈ hydrocarbylsulfonyl, aminosulfonyl, amino, nitro, and acetamide, or two adjacent R¹-R⁵ groups, together with the carbon atoms to which they are attached, may form a 4-, 5- or 6-membered carbocyclic ring.

2. A nanoparticle according to claim 1, wherein the Group 4 metal oxide is hafnium oxide or zirconium oxide.

3. A nanoparticle according to claim 1, wherein the Group 4 metal oxide is HfO₂.

4. A nanoparticle according to claim 1, wherein the ligand is a carboxylate of the organic acid according to Formula (I).

5. A nanoparticle according to claim 1, wherein R¹, R², R³, R⁴, and R⁵ are each individually selected from H, F, Cl, Br, —OH, —CH₃, —CH₂CH₂, —CH(CH₃)₂, —C(CH₃)₃, phenyl, —COCH₃, —OC(O)CH₃, —OCH₃, —OCH₂CH₃, O(CH₂) ₂CH₃, OCH(CH₃)₂, —O(CH₂)₃CH₃, —O(CH₂) ₄CH₃, phenoxy, —C(O)—O—CH₂CH₃, —C(O)OH, —CF₃, —OCF₃, —SCH₃, —SCH₂CH₃, —SCH(CH₃)₂, —SH, —CN, —SCN, —SOCH₃, —SO₂CH₃, —SO₂NH₂, —NH₂, —NO₂, and —NHC(O)CH₃.

6. A nanoparticle according to claim 5, wherein R¹, R², R³, R⁴, and R⁵ are individually selected from H, -F, —CH₃, —NH₂, —OH, —NO₂, and —CF₃.

7. A nanoparticle according to claim 1, wherein the ligand is para- or meta-substituted.

8. A nanoparticle according to claim 1, wherein R¹, R², R³, R⁴, and R⁵ are H.

9. A nanoparticle according to claim 8, wherein the ligand is a carboxylate of the organic acid according to Formula (I).

10. A nanoparticle according to claim 1, wherein the Group 4 metal oxide is ZrO₂ or HfO₂, and wherein the ligand is benzoic acid or a carboxylate thereof

11. A photoresist comprising the nanoparticle according to claim 1.

12. A photoresist composition comprising:
a nanoparticle comprising:
a core comprising a Group 4 metal oxide; and
a coating surrounding the core, said coating comprising a ligand selected from an acid and a carboxylate thereof and
a photoacid generator
wherein said photoacid generator is capable, upon photodecomposition, of generating an acid having a pKa lower than the pKa of the ligand acid.

13. A photoresist composition according to claim 12, wherein the Group 4 metal oxide is hafnium oxide or zirconium oxide.

14. A photoresist composition according to claim 12, wherein the Group 4 metal oxide is ZrO₂ or HfO₂, and wherein the ligand is benzoic acid or a carboxylate thereof, methacrylic acid or a carboxylate thereof, or trans-2,3 dimethylacrylic acid or a carboxylate thereof.

15. A photoresist composition according to claim 12, wherein the ligand is selected from an organic acid according to Formula (I): 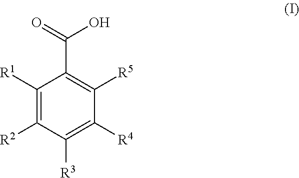
and a carboxylate thereof,
wherein R¹, R², R³, R⁴, and R⁵ are individually selected from hydrogen, C₁₋₈hydrocarbyl, halogen, hydroxyl, acyl, C₁₋₈hydrocarbylcarboxy, C₁₋₈ hydrocarbyloxy, C₁₋₈ hydrocarbyloxycarbonyl, carboxy, haloC₁₋₈hydrocarbyl, C₁₋₈ hydrocarbylthio, mercapto, cyano, thiocyanate, C₁₋₈hydrocarbylsulfinyl, C₁₋₈hydrocarbylsulfonyl, aminosulfonyl, amino, nitro, and acetamide,
or two adjacent R¹-R⁵ groups, together with the carbon atoms to which they are attached, may form a 5- or 6-membered carbocyclic ring.

16. A photoresist composition according to claim 12, wherein the ligand is selected from methacrylic acid, trans-2,3-dimethylacrylic acid, ethylacrylic acid, propylacrylic acid and methylbutyric acid, and carboxylates thereof

17. A photoresist composition according to claim 12, wherein the photoacid generator is nonionic.

18. A photoresist composition according to claim 12, wherein the photoacid generator is selected from N-hydroxynaphthalimide triflate, triphenylsulphonium triflate, and triphenylsulphonium perfluoro-1-butanesulphonate.

19. A photoresist composition according to claim 12, wherein the photoresist composition does not include a polymer that is sensitive to the photoacid generator.

20. A method for patterning a substrate, said method comprising:
forming a photoresist by applying on a substrate a photoresist composition according to claim 12;
imagewise exposing a defined region of the applied composition; and
developing the photoresist using positive tone development or negative tone development.
